(19) United States
(12) Patent Application Publication
(10) Pub. No.: US 2006/0113284 A1
(43) Pub. Date: Jun. 1, 2006

(54) Manufacturing method of substrate

(76) Inventor: Kazushige Umetsu, Chino, Nagano (JP)

Correspondence Address: HARNESS, DICKEY & PIERCE, P.L.C., P.O. BOX 828, BLOOMFIELD HILLS, MI, 48303, US

(21) Appl. No.: 11/239,566

(22) Filed: Sep. 29, 2005

(30) Foreign Application Priority Data
Nov. 5, 2004 (JP) 2004-322619

(51) Int. Cl. C23F 1/00; H01L 21/311; B23P 15/00

(52) U.S. Cl. 216/94; 438/700; 216/39

(57) ABSTRACT

Provided is a manufacturing method of a substrate capable of forming a pattern having a relatively narrow width and thick film based on a droplet discharging method. The manufacturing method of a substrate of the present invention is a manufacturing method of a substrate having a patterned functional film, including the steps of: forming a groove pattern on the substrate with laser irradiation; disposing a liquid material along the groove pattern; and heating the liquid material so as to form the functional film. Further, the groove pattern and a liquid repellent film may be combined. By using a liquid material, a highly dense and minute functional film (a wiring pattern for example) can be formed on the substrate.

### BACKGROUND

1. Field of the Invention

The present invention generally relates to a manufacturing method of a substrate having formed thereon a patterned layer having a function such as a signal wiring on the substrate, and in particular relates to a manufacturing method of a substrate in which such patterned layer is formed with a liquid material.

2. Description of the Related Art

In an electro-optic device such as a liquid crystal display device or an organic EL display device, the formation of an electrical wiring layer on a substrate is essential. The formation of this wiring layer on the substrate is conducted with the deposition of a conductive layer and the patterning of this film. The so-called photolithography method is used for the patterning. With this photolithography method, the formation of wiring on a large substrate beyond several ten inches is difficult. Further, high densification and miniaturization of the wiring width and wiring spacing are being demanded in a screen display device of a portable device and the like, and the wiring formation with the conventional photolithography method is becoming difficult. Thus, a droplet discharging method (inkjet (IJ) method) is attracting attention as direct drawing technology that does not require photomasking or etching. For instance, Japanese Patent Laid-Open Publication No. 2004-114370 describes an example of an inkjet method which miniaturizes the droplets for drawing.

### SUMMARY

Nevertheless, although the miniaturization of wiring will be possible by adopting the droplet discharging method which miniaturizes the droplets for drawing, the electrical resistance will increase when the wiring is thin. When overwriting is performed in order to lower the electrical resistance, the droplets will spread.

Further, in the droplet discharging method, if the lyophilic property of the substrate surface is high (wettability is high), droplets will spread easily, and it is difficult to miniaturize the line width. If the lyophilic property is lowered in order to suppress the spreading of droplets, the adhesiveness of the droplet to the substrate will be low, and the adhesiveness of the wiring cannot be obtained.

Accordingly, an object of the present invention is to provide a manufacturing method of a substrate capable of forming a pattern having a relatively narrow width and thick film based on a droplet discharging method.

In order to achieve the foregoing object, the manufacturing method of a substrate of the present invention is a manufacturing method of a substrate having a patterned functional film, including the steps of: forming a groove pattern on the substrate with laser irradiation; disposing a liquid material along the groove pattern; and hardening the liquid material so as to form the functional film.

According to the foregoing process, a liquid material can be used to form a highly dense and minute (wiring) pattern (functional film) on the substrate.

Preferably, the surface of the substrate is formed to have liquid repellency. The substrate is a flexible substrate formed from a resin material such as polyimide, epoxy or liquid crystal polymer. Further, this may also be a substrate formed from a transparent inorganic material such as quartz, Pyrex (registered trademark), low alkali, non alkali, soda, crystal or various ceramics.

Preferably, the lyophilic property of the groove pattern portion is improved with the laser irradiation.

Preferably, the laser irradiation is performed in a high concentration oxygen atmosphere where the oxygen concentration is 20% or more (20%-100%). Thereby, the lyophilic property of the groove pattern portion can be improved even more.

Preferably, a liquid repellent film is formed on the surface of the substrate, and the liquid repellent film is deteriorated or destroyed or removed with the laser irradiation.

Preferably, the substrate is a wiring substrate, and the liquid material is a wiring material. Or, a (non-conductive) film (or a non-conductive surface) that does not possess conductivity may be formed on the surface of this substrate in advance, and a wiring material may be disposed thereon. For example, a liquid material is a liquid material containing metal particles. Metal particles include particles of metals such as manganese, chrome, nickel, titanium, magnesium, silicon, vanadium, gold, silver, copper and palladium. Metal particles also include the particles of alloys containing these metals.

Preferably, the formation of the groove pattern is performed with the inkjet method, dipping method, liquid surface contact method or spraying method.

Preferably, the groove pattern portion of the substrate is an electrical wiring.

Preferably, the lyophilic property of the irradiated portion is improved in comparison to the lyophilic property of the non-irradiated portion via laser irradiation.

Preferably, liquid repellency is provided in advance to the non-irradiated portion in order to increase the difference with lyophilization based on laser irradiation and improve the controllability of the droplets.

Lyophilization of the laser irradiated portion of the substrate, for instance, may utilize the surface reforming phenomenon of the substrate. Further, lyophilization of the substrate based on laser irradiation may also be sought by removing the liquid repellent film previously formed on the substrate surface, or damaging the substrate surface (irradiated face) by laser abrasion.

Preferably, lyophilization of the laser irradiated portion of the substrate is conducted by performing laser irradiation in an oxygen atmosphere, for instance, in a high oxygen concentration atmosphere where the oxygen concentration is 20% or more (20%-100%) such that lyophilization can be realized easily.

Preferably, a groove portion is formed on the substrate with laser irradiation in order to realize a configuration where the capturing of droplets can be conducted with a three-dimensional structure. As the laser, an excimer laser, a solid laser (including a harmonic laser) such as a YAG laser, a semiconductor laser, a CO₂ laser and so on may be used.

Preferably, pattern irradiation with the laser is conducted with the pattern one-shot exposure system (imaging optical system) employing a mask, or a beam scanning system which performs relative scanning on the substrate with a beam spot.

With the beam scanning system, scanning may be performed by moving the substrate, or scanning may be performed by moving the laser beam with a Galvano scanner or rotating mirror. In the pattern one-shot exposure system, when it is necessary to irradiate a large surface area that cannot be irradiated with a single shot, a method of performing projection irradiation to the mask scan in which the area to be irradiated was divided may be adopted. Moreover, in the pattern one-shot exposure system, when it is necessary to irradiate a large surface area that cannot be irradiated with a single shot, a method of irradiating a laser beam in a state where a mask of the same size as the wiring pattern is placed on the substrate may be adopted.

Preferably, the substrate is a circuit substrate, and the functional film is one among a conductive film, insulation film and semiconductor film.

Further, with the manufacturing method of a substrate of the present invention, laser irradiation is performed in a high concentration oxygen atmosphere where the oxygen concentration is 20% or more (20%-100%).

Moreover, the electronics device of the present invention has the substrate manufactured with the manufacturing method described above.

### DESCRIPTION OF DRAWINGS

FIG. 1 is a process drawing for explaining the first embodiment of the present invention;

FIG. 2 is a process drawing for explaining the second embodiment of the present invention;

FIG. 3 is a process drawing for explaining the third embodiment of the present invention;

FIG. 4 is an explanatory diagram for explaining the spreading of a droplet;

FIG. 5 is an explanatory diagram for explaining the limit of forming a pattern with a droplet;

FIG. 6 is an explanatory diagram for explaining an example of a wiring substrate;

FIG. 7 is an explanatory diagram for explaining a pattern drawing example based on a focusing optical system;

FIG. 8 is an explanatory diagram for explaining a pattern drawing example based on an imaging optical system;

FIG. 9 is an explanatory diagram for explaining an example of electronics devices using the circuit board manufactured with the manufacturing method of the present invention; and

FIG. 10 is an explanatory diagram for explaining an example of an electronics device (TV) employing the circuit substrate manufactured with the manufacturing method of the present invention.

A highly dense and minute (wiring) pattern can be formed with the foregoing constitution.

### DETAILED DESCRIPTION

In the embodiments of the present invention, a liquid material is formed into a thick film by disposing the liquid material with a groove pattern formed on the substrate surface. Thereupon, the liquid material to be retained by the surface tension on the groove pattern is increased by further providing liquid repellency to the periphery of the groove pattern, and lyophilic property inside the groove pattern. By heating the liquid material, the functional component contained in the liquid material will harden and form a functional film. For example, a wiring film, insulation film or semiconductor film is formed as the functional film.

### Embodiment 1

Embodiments of the present invention are now explained with reference to the drawings.

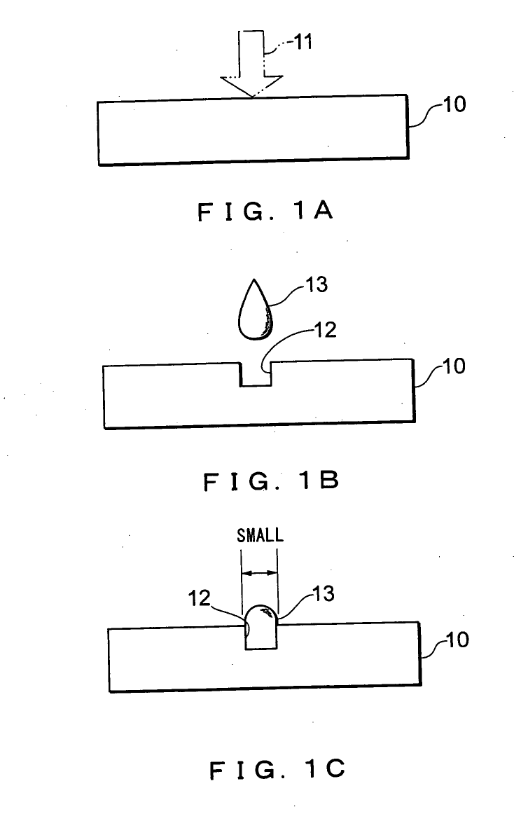

FIG. 1 shows the first embodiment of the present invention. As shown in FIG. 1A, a laser beam 11 is irradiated on a wiring substrate 10, and a groove pattern corresponding to a wiring pattern to be formed is formed with laser abrasion. The groove portion of the substrate formed with laser beam irradiation will deteriorate due to the energy of the laser beam, and the lyophilic property will relatively improve. Laser irradiation, for example, is conducted in an atmosphere where lyophilization can be easily realized such as in a high concentration oxygen atmosphere where the oxygen concentration is 20% or more (20%-100%).

As described later, the patterning of the substrate surface via irradiation of the laser beam 11 may be a pattern formation (pattern exposure) using a mask, or a pattern formation via laser beam scanning. The wiring substrate 10 is a flexible substrate formed from a resin material such as polyimide, epoxy or liquid crystal polymer. Further, the wiring substrate 10 may also be a substrate formed from a transparent inorganic material such as quartz, Pyrex (registered trademark), low alkali, non alkali, soda, crystal or various ceramics.

Next, as shown in FIG. 1B, a liquid material 13 is discharged as a droplet from a droplet discharging head (inkjet head) not shown with a droplet discharging method along a wiring groove pattern 12 formed on the substrate surface, and disposed in the groove pattern 12. The liquid material 13 contains one or a plurality of metal particles (conductive materials) in the dispersion medium. For example, as the solvent, water, alcohol, hydrocarbon compound, ether compound and so on may be used. Metal particles include particles of metals such as manganese, chrome, nickel, titanium, magnesium, silicon, vanadium, gold, silver, copper and palladium, as well as the alloys thereof. The diameter of the metal particles, for instance, is preferably 1 nm or greater and 0.1 μm or less in consideration of the clogging of the nozzle and so on when using a droplet discharging head for the disposition of the liquid material.

As shown in FIG. 1C, when the liquid material 13 is disposed in the wiring groove pattern 12 of the substrate 10, a thick liquid material film is formed based on the surface tension of the liquid material 13, depth of the groove 12, and the lyophilic property of the wall surface of the groove 12. Thereafter, the wiring substrate 10 is subject to heat treatment via thermal treatment or light irradiation in order to vaporize the dispersive material in the liquid material 13, metal particles are sintered, and a conductive film (wiring film) is formed thereby. Since this wiring film will be formed relatively thick with the groove 12 and lyophilic treatment even when employing the droplet discharging method, a desired value of resistance and adhesiveness of the wiring to the substrate can be obtained.

### Embodiment 2

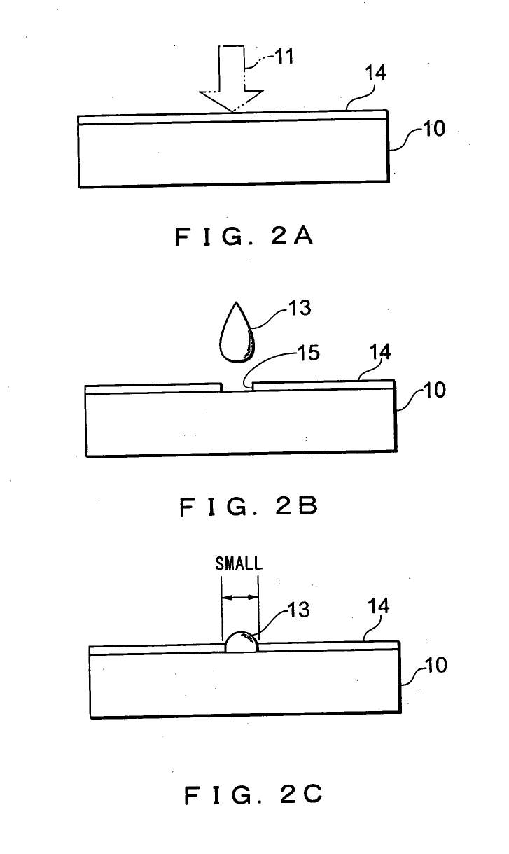

FIG. 2 shows the second embodiment of the present invention. In FIG. 2, the same reference numerals are given to the components corresponding to those illustrated in FIG. 1, and the explanation thereof is omitted.

In the present embodiment, as shown in FIG. 2A, a liquid repellent film 14 is formed in advance on the surface of the wiring substrate 10. As the liquid repellent film 14, for example, Teflon (registered trademark), tetrafluoroethylene polyimide film or the like may be used. Incidentally, it is desirable that the surface of the wiring substrate 10 is subject to lyophilic treatment. For example, the lyophilic property against the liquid material 13 can be improved via plasma processing.

Next, a laser beam 11 is irradiated on the wiring substrate 10 in order to partially destroy/remove the liquid repellent film 14 and expose the substrate 10, and a groove pattern 15 corresponding to the wiring pattern to be formed is formed thereby. The portion where the substrate 10 is exposed from the liquid repellent film 14 corresponds to the wiring pattern. Preferably, the surface of the exposed substrate 10 has lyophilic property. Laser irradiation, for example, is desirably conducted in an atmosphere where lyophilization can be easily realized such as in a high concentration oxygen atmosphere where the oxygen concentration is 20% or more (20%-100%).

As shown in FIG. 2B, a liquid material 13 is discharged from a droplet discharging head not shown with a droplet discharging method along an opening (groove) pattern 15 of the liquid repellent film 14 formed on the surface of the substrate 10, and disposed in the groove pattern 15. As described above, the liquid material 13 contains metal particles.

As shown in FIG. 2C, when the liquid material 13 is disposed in the opening pattern 15 of the liquid repellent film 14, a thick liquid material film is formed at the opening pattern 15 of the liquid repellent film 14 based on the surface tension of the liquid material 13, liquid repellent film 14, and the lyophilic property of the surface of the substrate 10. Thereafter, the wiring substrate 10 is subject to heat treatment via thermal treatment or light irradiation in order to vaporize the dispersive material in the liquid material 13, metal particles are sintered, and a conductive film (wiring film) is formed thereby. Since this wiring film will be formed relatively thick with the liquid repellent film 14 and lyophilic treatment even when employing the droplet discharging method, a desired value of resistance and adhesiveness of the wiring to the substrate can be obtained.

As described above, as a result of the surface of the substrate 10 possessing lyophilic property, or by interposing a lyophilic film between the substrate 10 and liquid repellent film 14, the liquid material of the opening (groove) portion 15 can be retained as an even thicker film.

### Embodiment 3

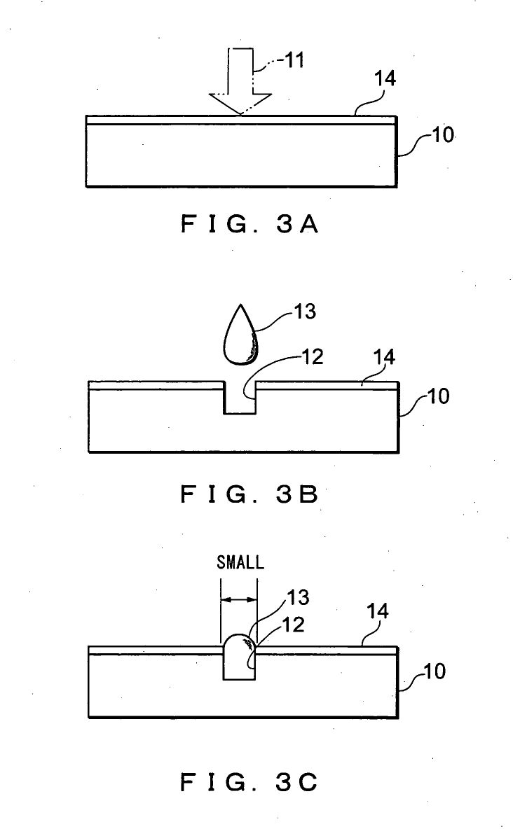

FIG. 3 shows the third embodiment of the present invention. In FIG. 3, the same reference numerals are given to the components corresponding to those illustrated in FIG. 1, and the explanation thereof is omitted.

In the present embodiment, as shown in FIG. 3, the groove 12 of the substrate surface 10 and the liquid repellent film 14 are used in combination. A laser beam 11 is irradiated on the wiring substrate 10 with the liquid repellent film 14 formed thereon, and a groove pattern corresponding to a wiring pattern to be formed is formed thereby. The groove portion 12 of the substrate 10 formed with laser beam irradiation will deteriorate due to the energy of the laser beam 11, and the lyophilic property will relatively improve. As described above, laser irradiation, for example, is desirably conducted in an atmosphere where lyophilization can be easily realized such as in a high concentration oxygen atmosphere where the oxygen concentration is 20% or more (20%-100%).

Next, a liquid material 13 is discharged from a droplet discharging head not shown with a droplet discharging method along a wiring groove pattern 12 formed on the substrate surface, and disposed in the groove pattern 12.

As shown in FIG. 3C, when the liquid material 13 is disposed in the wiring groove pattern 12 of the substrate 10, a thick liquid material film is formed based on the surface tension of the liquid material 13, liquid repellent film 14, depth of the groove 12, and the lyophilic property of the wall surface of the groove 12.

Thereafter, the wiring substrate 10 is subject to heat treatment via thermal treatment or light irradiation in order to vaporize the dispersive material in the liquid material 13, metal particles are sintered, and a conductive film (wiring film) is formed thereby. Since this wiring film will be formed relatively thick with the groove 12, liquid repellent film 14, and lyophilic treatment even when employing the droplet discharging method, a desired value of resistance and adhesiveness of the wiring to the substrate can be obtained even easier.

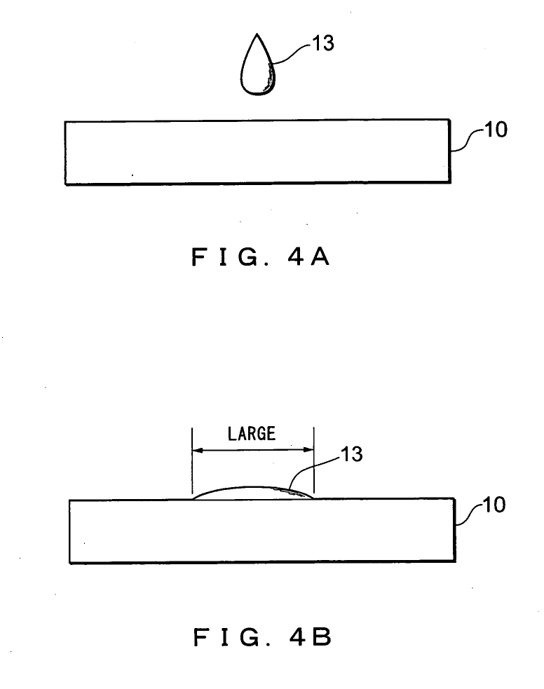

FIG. 4 to FIG. 6 show the comparative examples with the present invention.

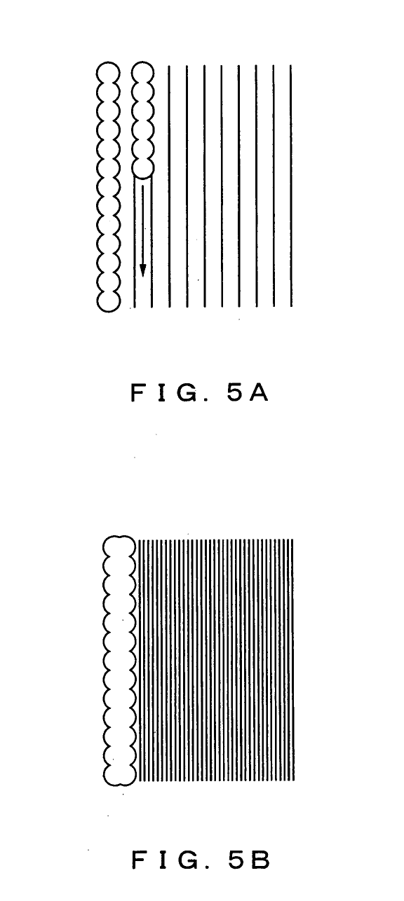

As shown in FIG. 4A, when a liquid material is discharged on a substrate, as shown in FIG. 4B, the liquid material will spread outward from its impact position. Further, as shown in FIG. 5, when patterning is performed by discharging the liquid material and the drawing interval of the lines becomes narrow, the disposed liquid materials will become connected. Thus, it is difficult to realize further high densification and miniaturization of the wiring width or wiring spacing in forming a wiring film with a liquid material.

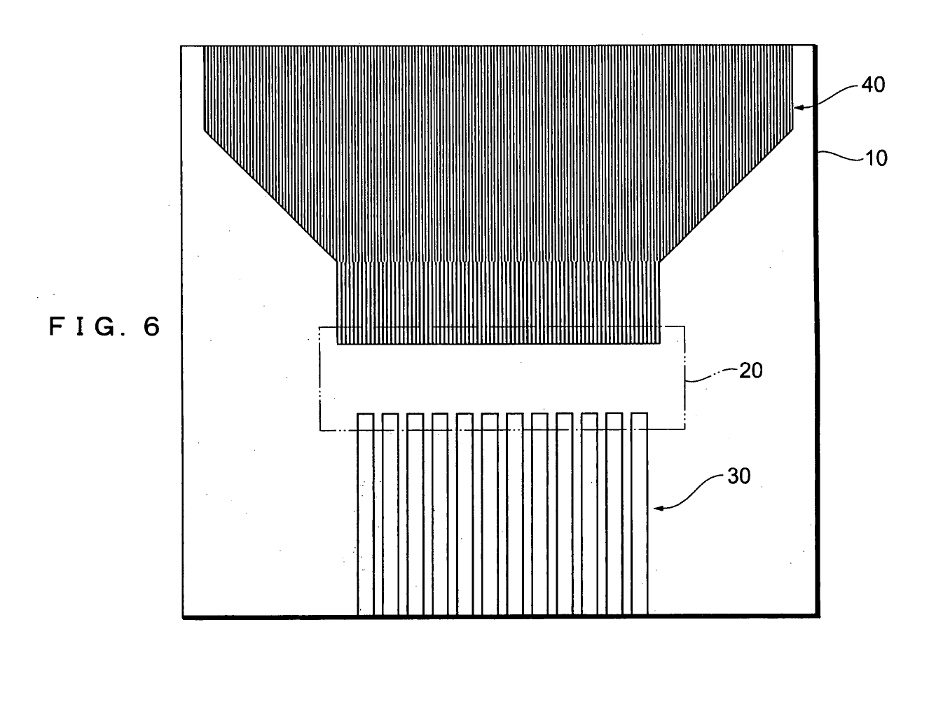

FIG. 6 shows an example of an FPC (Flexible Printed Circuit) substrate used in electro-optic devices. Although a relatively broad signal line 30 is used as the signal input line 30 to the drive circuit 20 of the display unit, a signal output line 40 output from the drive circuit 20 for driving the numerous pixel lines of the display unit has an extremely narrow line width and wiring spacing. Therefore, by employing the present invention, the technique of forming a thin line width and a thick film wiring will be useful.

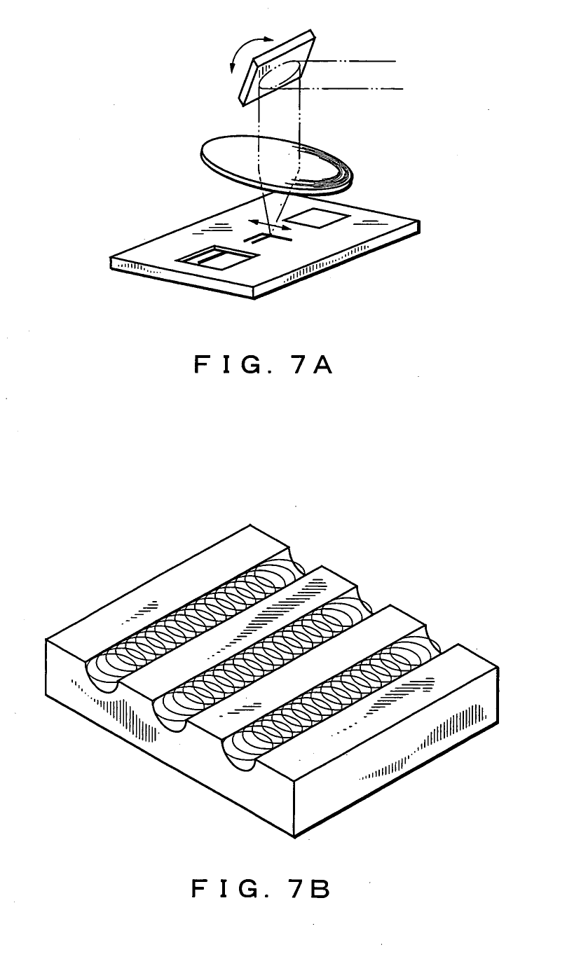

FIG. 7 is an explanatory diagram for explaining an example of patterning with laser irradiation. FIG. 7A shows an example of combining a focusing optical system and a scanning system, and patterning is performed on the substrate via the scanning of a laser beam spot in which the amount of light is modulated with information. When laser irradiation is performed in a pulse such as with an ultraviolet YAG laser, as shown in FIG. 7B, irregularities will be formed on the bottom face (wall face) of the groove formed with irradiation spot tracking. Thereby, the effect of increased lyophilic property can be acknowledged. Further, the effect of increased lyophilic property due to the deterioration of the substrate surface caused by laser irradiation can also be acknowledged.

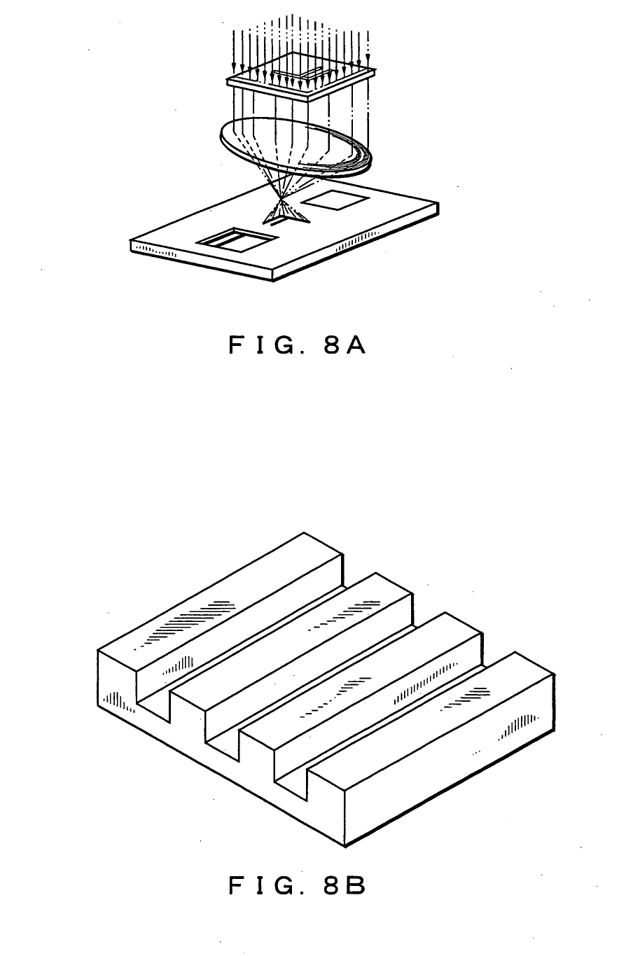

FIG. 8 is an explanatory diagram for explaining another pattering example via laser irradiation. FIG. 8A shows an example of combining an imaging optical system and a mask, and patterning is performed on the substrate via surface irradiation of the laser beam in which the amount of light is modulated with the mask. For example, when pattern one-shot irradiation is performed with an excimer laser, as shown in FIG. 8B, the shape of the groove in the substrate will be formed sharp. The effect of increased lyophilic property by the formation of the groove and the deformation of the groove portion via laser irradiation can also be acknowledged.

In each of the foregoing embodiments, although the liquid material was disposed in the groove pattern portion with the droplet discharging method, the present invention is not limited thereto. For instance, when the liquid repellent film 14 is formed on the substrate surface (when the substrate surface other than the groove pattern is made to have liquid repellency), the dipping method of dipping the entire substrate in the liquid material solution, the surface contact method of making the substrate surface contact the liquid level of the liquid material, the spraying method of spraying the atomized liquid material on to the substrate surface and other methods may be suitably selected and used.

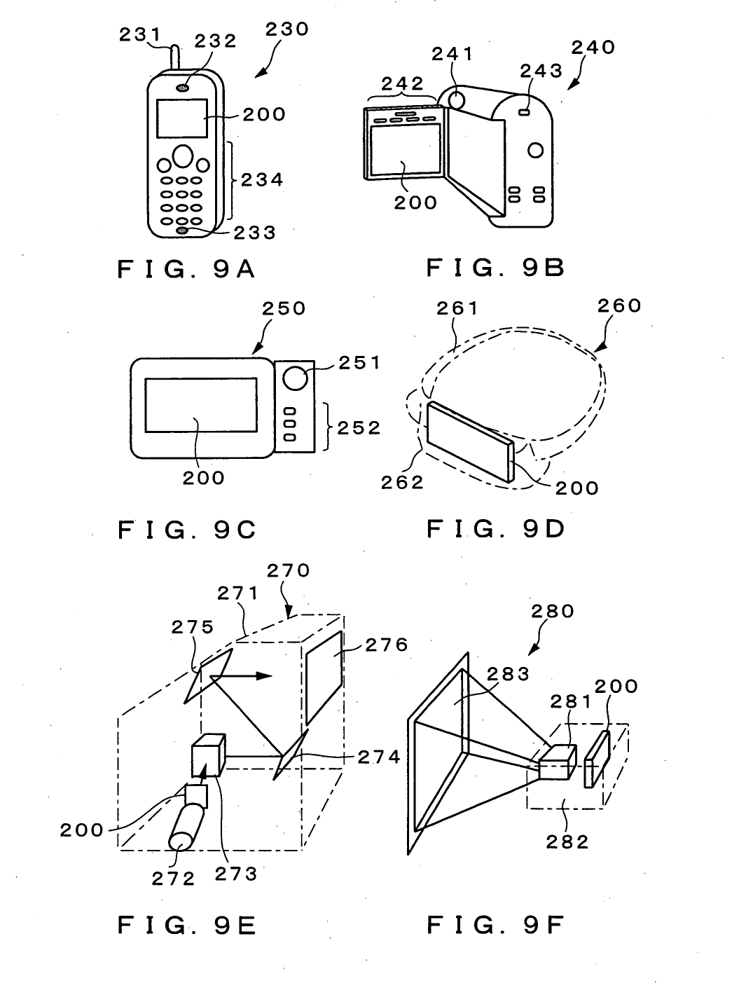

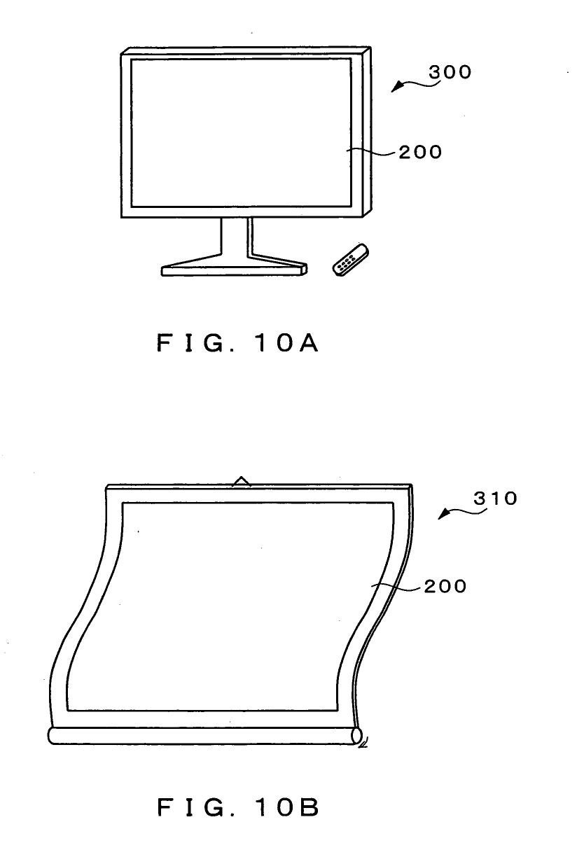

FIG. 9 and FIG. 10 are diagrams showing examples of electronics devices using the circuit substrate manufactured with the foregoing manufacturing method of a substrate.

FIG. 9A is an application example in a mobile phone, and this mobile phone 230 has an antenna unit 231, a sound output unit 232, a sound input unit 233, an operating unit 234, and an electro-optic device 200 of the present invention. In this manner, the electro-optic device of the present invention can be used as a display unit.

FIG. 9B is an application example in a video camera, and this video camera 240 has an image receiving unit 241, an operating unit 242, a sound input unit 243, and the electro-optic device 200 of the present invention.

FIG. 9C is an application example in a portable personal computer (so-called PDA), and this computer 250 has a camera unit 251, an operating unit 252, and the electro-optic device 200 of the present invention. FIG. 9D is an application example in a head-mount display, and this head-mount display 260 has a band 261, an optical system housing unit 262 and the electro-optic device 200 of the present invention.

FIG. 9E is an application example in a rear-type projector, and this projector 270 has, in its case 271, a light source 272, a composite optical system 273, mirrors 274, 275, a screen 276, and the electro-optic device 200 of the present invention. FIG. 9F is an application example in a front-type projector, and this projector 280 has, in its case 282, an optical system 281 and the electro-optic device 200 of the present invention, and is capable of display images on a screen 283.

FIG. 10A is an application example in a TV, and this TV 300 has the electro-optic device 200 of the present invention. Incidentally, the electro-optic device of the present invention may also be similarly applied to a monitor device of personal computers and the like.

FIG. 10B is an application example in a rollup-type TV, and this rollup-type TV has the electro-optic device 200 of the present invention.

As described above, according to the embodiments of the present invention, since a groove pattern is formed on the substrate surface, and also by using the liquid repellent film formed around this groove pattern and the lyophilization inside the groove pattern, the liquid material can be patterned in a thin line width and in a thick film. Thus, a liquid material can be used form minute patterns.

Incidentally, in the foregoing embodiments, although a wiring film was exemplified as the functional film to be formed with the liquid material on the substrate 10, the present invention is not limited thereto. For example, an insulation film or semiconductor film may also be the functional film. Here, organic silicon or liquid semiconductor material may be used as the liquid material.

Further, a (non-conductive) film (or a non-conductive surface) that does not possess conductivity may be formed on the surface of the substrate 10 in advance, and a wiring material may be disposed thereon.

1. A manufacturing method of a substrate having a patterned functional film, comprising the steps of:
forming a groove pattern on the substrate with laser irradiation;
disposing a liquid material along said groove pattern; and
hardening said liquid material so as to form said functional film.

2. The manufacturing method of a substrate according to claim 1, wherein the surface of said substrate is formed to have liquid repellency.

3. The manufacturing method of a substrate according to claim 1, wherein the lyophilic property of said groove pattern portion is improved with said laser irradiation.

4. The manufacturing method of a substrate according to claim 1, wherein said laser irradiation is performed in a high concentration oxygen atmosphere where the oxygen concentration is 20%-100%.

5. The manufacturing method of a substrate according to claim 1, wherein a liquid repellent film is formed on the surface of said substrate, and said liquid repellent film is deteriorated or destroyed or removed with said laser irradiation.

6. The manufacturing method of a substrate according to claim 1, wherein said substrate is a wiring substrate, and said liquid material is a wiring material.

7. The manufacturing method of a substrate according to claim 1, wherein said substrate is a circuit substrate, and said functional film is one among a conductive film, insulation film and semiconductor film.

8. A manufacturing method of a substrate wherein laser irradiation is performed in a high concentration oxygen atmosphere where the oxygen concentration is 20%-100%.

9. An electronics device comprising the substrate manufactured with the manufacturing method according to claim 1.

10. An electronics device comprising the substrate manufactured with the manufacturing method according to claim 8.
